(19) United States
(12) Patent Application Publication
(10) Pub. No.: US 2009/0191716 A1
(43) Pub. Date: Jul. 30, 2009

(54) POLYSILICON LAYER REMOVING METHOD AND STORAGE MEDIUM

(75) Inventor: Mitsunori Nakamori, Nirasaki City (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/362,909

(22) Filed: Jan. 30, 2009

(30) Foreign Application Priority Data
Jan. 30, 2008 (JP) 2008-019506

(51) Int. Cl. H01L 21/465; G06F 17/00

(52) U.S. Cl. 438/746; 700/121; 257/E21.485

(57) ABSTRACT

A polysilicon layer removing method capable of substantially removing etching residue, while improving the shape of an etching boundary is disclosed. The method for removing the polysilicon layer from a beveled portion of a wafer W through wet etching includes hydrophilizing the polysilicon layer, without removing the polysilicon layer from the beveled portion, and supplying an etchant having the mixture of hydrofluoric acid and nitric acid onto the hydrophilized polysilicon layer of the beveled portion, while the wafer is rotated at revolutions enough for flattening an etching boundary.

This application is based on and claims priority from Japanese Patent Application No. 2008-019506, filed on Jan. 30, 2008 in the Japanese Patent Office, the disclosure of which is incorporated herein in its entirety by reference.

### TECHNICAL FIELD

The present invention relates to a polysilicon layer removing method and a storage medium, capable of removing a polysilicon layer from an end of a substrate, such as a semiconductor wafer, on which the polysilicon layer formed, through wet etching.

### BACKGROUND

Semiconductor manufacturing processes include forming several thin films on semiconductor wafers (hereinafter simply “wafers”). During the processes, beveled portions (i.e., ends) of wafers are likely suffered from crack or peeling. Particles resulted from cracks or peelings will contaminate semiconductor devices.

Recently, liquid immersion lithography has been used as photolithography technology to achieve high resolution of 45 nm node in semiconductor devices. However, the peeled layers of the beveled portions of waters are lifted off by water during the liquid immersion lithography, thereby causing defects in semiconductor devices. Thus, contamination problem will be further serious in using the liquid immersion lithography.

As such, wet etching has been proposed to remove beveled portions of wafers. The wet etching supplies chemicals onto the beveled portions of wafers on which layers are formed while rotating wafers. Japanese Patent Unexamined Publication No. 2001-319850 discloses an example of the wet etching.

One example of the layers formed on wafers is a polysilicon layer used for a gate electrode. When polysilicon layers are processed through wet etching, a mixture of hydrofluoric acid and nitric acid is generally used as chemicals.

A wet etching apparatus for the beveled portion of single wafer type should ensure proper revolutions of wafers to improve the shape of an etching boundary by a centrifugal force.

Polysilicon layers have a hydrophobic property. Thus, if the revolutions of the wafer on etching are increased to improve the shape of the etching boundary, the mixture of hydrofluoric acid and nitric acid rarely adheres to the polysilicon layer, and polysilicon is remained on the beveled portion in a strip pattern.

### SUMMARY

The present invention provides a polysilicon layer removing method, capable of removing a polysilicon layer from an end of a substrate, in which etching residue is not substantially remained, while improving the shape of an etching boundary.

Also, the present invention provides a storage medium storing a program to execute the polysilicon layer removing method.

According to one example, a method for removing a polysilicon layer from an end of a substrate through wet etching is provided. The method includes hydrophilizing the polysilicon layer, without removing the polysilicon layer from the end of the substrate, and supplying an etchant, the etchant including a mixture of hydrofluoric acid and nitric acid, onto the hydrophilized polysilicon layer formed on the end of the substrate, while the substrate is rotated at revolutions enough for improving the shape of an etching boundary.

In some examples, the etchant may be supplied while the substrate is rotated at 300 rpm or more. The etchant may include the hydrofluoric acid and the nitric acid at a volume ratio of 1:1 to 1:30. Also, in some examples, a supply amount of the etchant may be 3 to 50 cm³/min.

The hydrophilizing may be performed by supplying the nitric acid onto the polysilicon layer formed on the end of the substrate to oxidize the polysilicon layer. In this instance, the hydrophilizing may be performed by supplying the nitric acid onto the polysilicon layer formed on the end of the substrate to oxidize the polysilicon layer while the substrate is rotated at 600 rpm or less.

Also, the hydrophilizing may be performed by supplying any one of a hydrogen peroxide solution, an ozonized water and an ozone gas onto the polysilicon layer formed on the end of the substrate to oxidize the polysilicon layer.

The hydrophilizing may be performed by irradiating light onto the polysilicon layer formed on the end of the substrate. The light irradiated onto the polysilicon layer may be ultraviolet rays.

In another example, a computer readable storage medium storing a program that controls a processing apparatus is provided. The program is executed by the computer to control the processing apparatus to perform the polysilicon layer removing method.

According to the present invention, since the hydrophilization is performed without removing the polysilicon layer from the end of the substrate prior to the supply of the etchant, the polysilicon layer can be wetted by the etchant including the mixture of hydrofluoric acid and nitric acid even when the substrate is rotated at revolutions enough for improving the shape of an etching boundary. Further, etching residue is not substantially remained while improving the shape of the etching boundary.

### BRIEF DESCRIPTION OF THE DRAWINGS

FIG. 1 is a view schematically illustrating a processing apparatus according to an embodiment of the present invention;

FIG. 2 is a flowchart illustrating a polysilicon removing method according to an embodiment of the present invention;

FIGS. 3A to 3D are views illustrating each step of a polysilicon removing method according to an embodiment of the present invention;

FIG. 4 is a view illustrating a state of a beveled portion when removing a polysilicon layer from the beveled portion while a wafer is rotated at low speed, without performing hydrophilization with respect to the wafer;

FIG. 5 is a view illustrating a state of a beveled portion when removing a polysilicon layer from the beveled portion while a wafer is rotated at high speed, without performing hydrophilization with respect to the wafer;

FIG. 6 is a view illustrating a state of a beveled portion when removing a polysilicon layer from the beveled portion while a wafer is rotated at high speed, after performing hydrophilization with respect to the wafer according to the present invention; and

FIG. 7 is a view illustrating an apparatus for performing the method according to another embodiment of the present invention.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

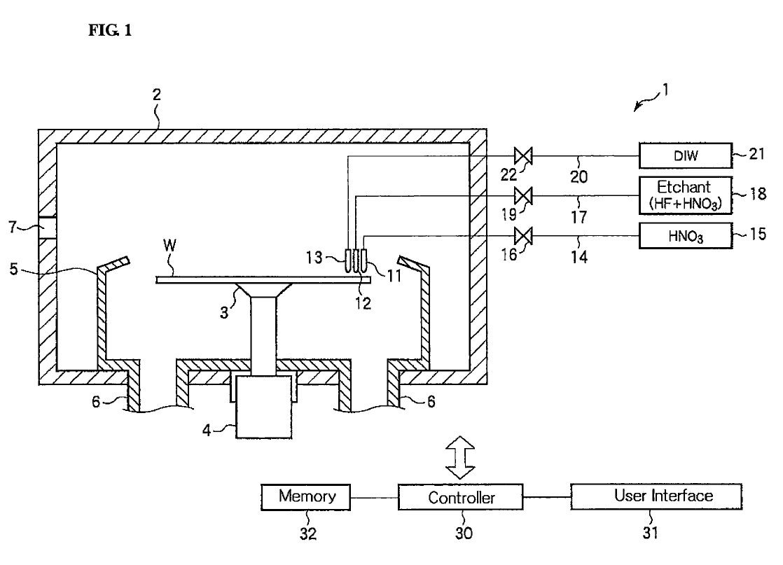

FIG. 1 is a view schematically illustrating a processing apparatus according to an embodiment of the present invention.

A processing apparatus 1 includes a chamber 2. The chamber 2 includes a spin chuck 3 to sustain a processed wafer W, on which a polysilicon layer is formed, by vacuum adsorption in a horizontal level. The spin chunk 3 is adapted to rotate by a motor 4. A cup 5 is provided within the chamber 2 to cover the wafer W sustained by the spin chuck 3. An air/liquid drain duct 6 is formed on the bottom of the cup 5 to extend downwardly from the chamber 2. The air/liquid drain duct 6 discharges air and liquid. A loading/unloading port 7 is formed at the sidewall of the chamber 2. The loading/unloading port 7 loads and unloads the wafer W A nitric acid supply nozzle 11 to supply nitric acid (HNO₃), an etchant supply nozzle 12 to supply an etchant, for example, a mixture of hydrofluoric acid (HF) and nitric acid (HNO₃), and a deionized water supply nozzle 13 to supply a deionized water (DIW) are provided over the end of the wafer W sustained by the spin chuck 3. These nozzles 11 to 13 are vertically and horizontally movable by a driving tool (not shown).

One end of a nitric acid supply duct 14 is connected to the nitric acid supply nozzle 11, and the other end of the nitric acid supply duct 14 is connected to a nitric acid supply source 15. The nitric acid supply duct 14 is provided with a valve 16. One end of an etchant supply duct 17 is connected to the etchant supply nozzle 12, and the other end of the etchant supply duct 17 is connected to an etchant supply source 18. The etchant supply duct 17 is provided with a valve 19. One end of a deionized water supply duct 20 is connected to the deionized water supply nozzle 13, and the other end of the deionized water supply duct 20 is connected to a deionized water supply source 21. The deionized water supply duct 20 is provided with a valve 22.

Each component of the processing apparatus 1, for example, the motor 4, the valves 16, 19 and 22, the driving tool of the nozzles 11 to 13, and so forth, is adapted to be controlled by a controller 30 having a microprocessor (i.e., a computer). The controller 30 is connected to a user interface 31. The user interface 31 includes a keyboard to input a command to control the processing apparatus 1, a display to visualize a driving circumference of the processing apparatus 1, and so forth. Also, the controller 30 is connected to a memory 32 stored with a control program to control a target of each component of the processing apparatus 1 or a program to allow the processing apparatus 1 to perform predetermined processes, i.e., a recipe. The recipe is stored in a memory medium of the memory 32. The memory medium may be stationary, such as a hard disc, or may be portable, such as CDROM, DVD or flash memory. The recipe may be transmitted from other device, for example, via a dedicated cable. If necessary, an arbitrary recipe is called from the memory 32 in response to indication from the user interface 31, so as to execute the controller 30, so that desired process is performed under the control of the controller 30.

A method for removing the polysilicon layer from a beveled portion of the wafer W by using the processing apparatus will now be described.

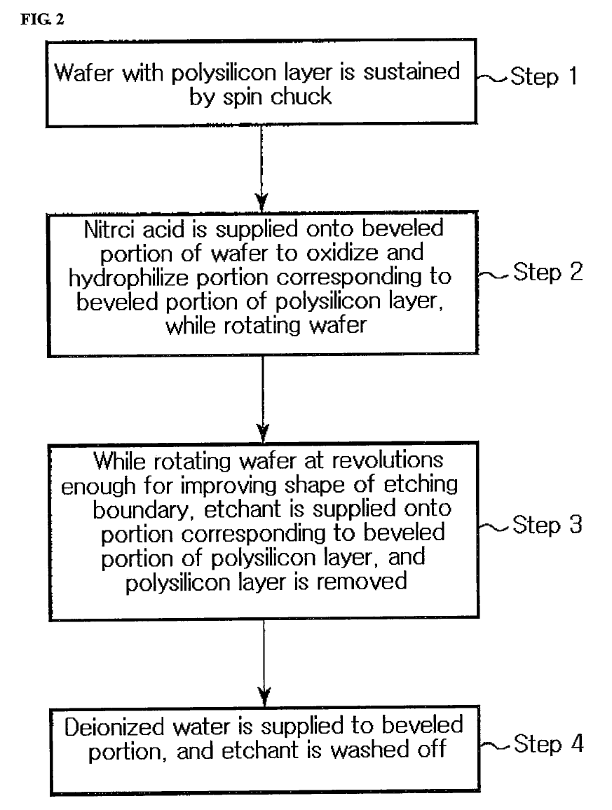

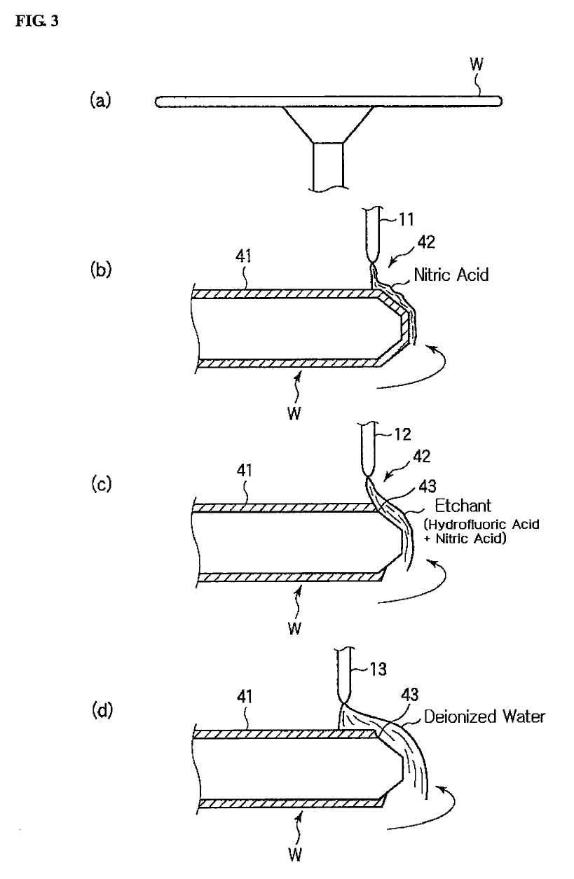

FIG. 2 is a flowchart illustrating the polysilicon layer removing method, and FIG. 3 is a view illustrating each step of the method.

Referring to FIG. 2, the wafer W is loaded in the chamber 2 and is sustained by the spin chuck 3 (Step 1) (FIG. 3A). On the entire surface of the wafer W, a polysilicon layer 41 is formed through a thermal oxidization layer (not shown).

Next, the nitric acid supply nozzle 11 is positioned over a beveled portion 42 of the wafer W, and nitric acid is supplied onto the beveled portion 42 of the wafer W from the nitric acid supply nozzle 11, while the wafer W is rotated in predetermined revolutions. The portion corresponding to the beveled portion 42 of the polysilicon layer 41 is not removed, and is oxidized to be hydrophilized (step 2) (FIG. 3B). The revolutions of the wafer W are preferably set in such a way that polysilicon is sufficiently wetted and oxidized by the nitric acid. The revolutions may be 600 rpm or less. The polysilicon layer 41 of the beveled portion 42 can be hydrophilized during a short time of about 5 seconds through this step.

The etchant supply nozzle 12 is positioned over the beveled portion 42 of the wafer W, and the mixture of the hydrofluoric acid and the nitric acid as an etchant is supplied onto the portion corresponding to the beveled portion 42 of the hydrophilized polysilicon layer 41, while the wafer W is rotated at revolutions enough for improving the shape of etching boundary (step 3) (FIG. 3C). As a result, the portion of the polysilicon layer 41 corresponding to the hydrophilized beveled portion 42 can be removed so that etching residue is not remained while improving the shape of the etching boundary 43.

As the portion is previously hydrophilized by the nitric acid, the polysilicon layer 41 can be sufficiently wetted and etched by the mixture of hydrofluoric acid and nitric acid, although the wafer W is rotated at fast revolutions enough for improving the shape of the etching boundary. Also, the polysilicon layer 41 of the beveled portion 42 can be almost fully removed while improving the shape of the etching boundary 43 of the beveled portion 42.

For example, the revolutions of the wafer W are high in order to improve the shape of the etching boundary 43. In particular, the revolutions of the wafer W are 300 rpm or more at etching in order to achieve the precision of the etching boundary of ±0.2 mm or less. For example, the revolutions are 500 rpm or more so as to secure the precision of the etching boundary of ±0.1 mm. The upper limit of the revolutions is not limited to, but includes 5000 rpm or less. As an excessive supply amount of the mixture of hydrofluoric acid and nitric acid may cause the shape of the etching boundary to deteriorate, the supply amount of the mixture is low, for example, 3 to 50 cm³/min, or 10 cm³/min. The precision of the etching boundary means the maximum value of variations to a target etching width at an edge of the wafer W.

For example, the mixture of hydrofluoric acid and nitric acid used as the etchant includes the hydrofluoric acid and the nitric acid at a volume ratio of 1:1 to 1:30. Also, dilution of the mixture is, for example, 0 to 30%.

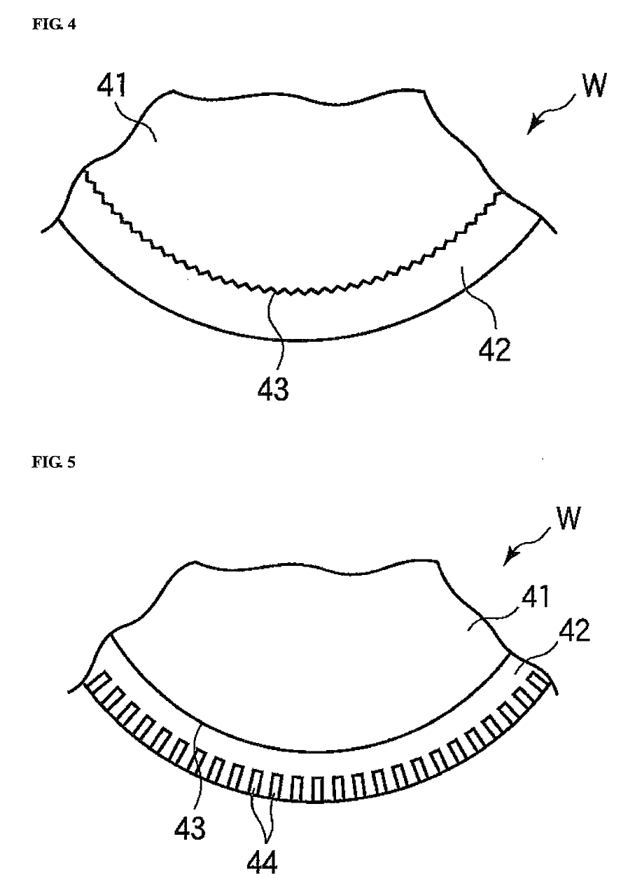

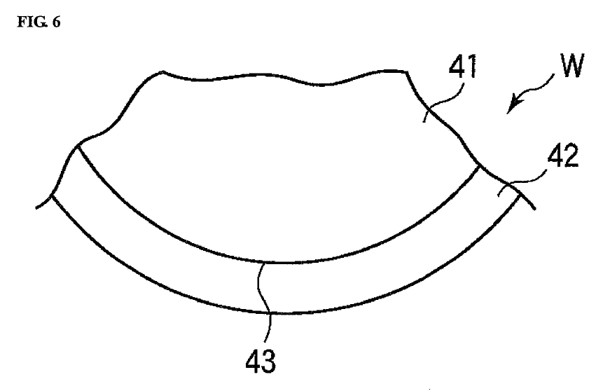

Even if the portion corresponding to the beveled portion of the polysilicon layer is not hydrophilized, the polysilicon of the beveled portion can be removed by supplying the mixture of hydrofluoric acid and nitric acid while rotating the wafer at low speed of about 100 rpm. But, the shape of the etching boundary 43 may become improper, as shown in FIG. 4, because of insufficient centrifugal force. Thus, if the wafer W is rotated at high speed of about 1000 rpm to improve (flatten) the shape of the etching boundary, the polysilicon layer is not wetted by the etchant, so that etching residue 44 is produced in a strip pattern, as shown in FIG. 5. The polysilicon removing method according to the present invention can solve the above-described contradictable problems, while improving the shape of the etching boundary 43 of the beveled portion 42 and almost removing etching residue.

After the etching is performed as described above, the deionized water supply nozzle 13 is moved over a portion about 1 mm interiorly spaced apart from the etchant supplying portion of the beveled portion. Then, the etchant including the mixture of hydrofluoric acid and nitric acid is washed off while the wafer W is rotated at speed of 30 to 1500 rpm (step 4) (FIG. 3D).

According to the above-described method, the process for removing the polysilicon from the beveled portion of the wafer W through the wet etching is completed.

An example embodiment to test the effects of the present invention will now be described.

A Si wafer with a polysilicon layer having a thickness of 150 nm which was formed on a thermal oxidization layer having a thickness of 100 nm was used.

A mixture was prepared to mix hydrofluoric acid (50% aqueous solution) and nitric acid (61% aqueous solution) at a volume ratio of 1 to 5, and the mixture was used as an etchant. Nitric acid (61% aqueous solution) was used as a hydrophilization processing liquid.

The mixture of hydrofluoric acid and nitric acid was supplied onto the beveled portion to remove the polysilicon layer, without the hydrophilization, while the wafer was rotated at 100 rpm and 1000 rpm. The mixture of hydrofluoric acid and nitric acid was supplied at a flow rate of 10 cm3/min by using a nozzle of 0.3 mmΦ. As a result, at the revolutions of 100 rpm, although the polysilicon was removed from the beveled portion, the shape of the etching boundary was improper and the precision was more than ±0.2 mm. Meanwhile, at the revolutions of 1000 rpm, the polysilicon layer was not sufficiently wetted by the mixture, and thus the polysilicon layer was remained on the beveled portion in a strip pattern.

After the hydrophilization was performed, the mixture of hydrofluoric acid and nitric acid was supplied onto the beveled portion to remove the polysilicon layer while the wafer was rotated at 1000 rpm. The hydrophilization was performed by supplying nitric acid at a flow rate of 10 cm³/min by using a nozzle of 0.3 mmΦ, while the wafer was rotated at revolutions of 500 rpm. The etching is removed by supplying the mixture at a flow rate of 10 cm³/min by using a nozzle of 0.3 mmΦ, as described above. As a result, the polysilicon was completely removed from the beveled portion, and the precision of the etching boundary was less than ±0.2 mm.

Thus, if the polysilicon layer is removed from the beveled portion by using the mixture of hydrofluoric acid and nitric acid after the wafer is hydrophilized according to the present invention, the shape of the etching boundary is good, and etching residue is not remained.

The present invention is not limited to the above embodiment, and several modifications can be achieved. For example, although the polysilicon layer is oxidized by using the nitric acid to hydrophilize the polysilicon layer, the polysilicon layer can be oxidized by using other hydrophilization agent. A hydrogen peroxide solution or ozonized water may be used as the hydrophilization agent, and may be supplied by a nozzle, like the nitric acid. Also, an ozone gas may be used as the hydrophilization agent, and may be supplied by a nozzle.

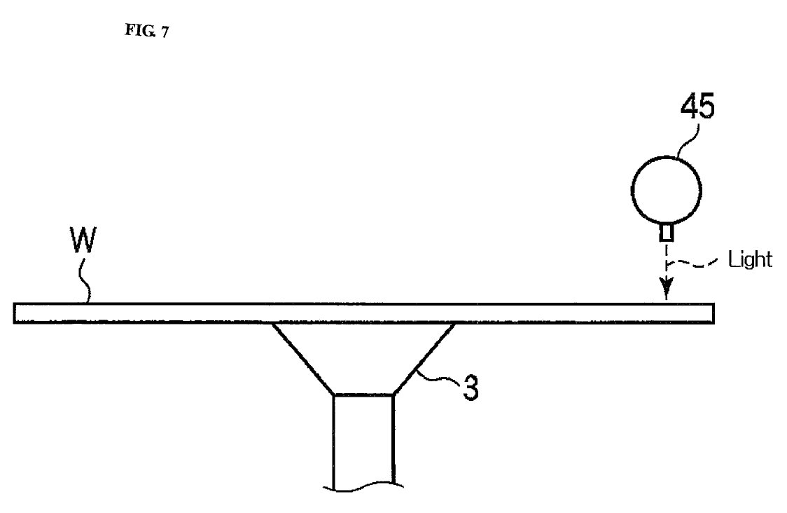

Also, the polysilicon layer may be hydrophilized by irradiating light onto the layer. As shown in FIG. 7, a light source 45, for example, a ultraviolet lamp, is positioned over the beveled portion 42 of the wafer W, and lights such as ultraviolet rays are irradiated onto the wafer W, while the wafer is rotated at low speed.

Although the embodiment is applied to the semiconductor wafer such as Si wafer, the present invention is not limited to the embodiment.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method for removing a polysilicon layer from an end of a substrate through wet etching, comprising:
hydrophilizing a polysilicon layer, without removing the polysilicon layer from the end of a substrate; and
supplying an etchant, the etchant including a mixture of hydrofluoric acid and nitric acid, onto the hydrophilized polysilicon layer formed on the end of the substrate, while the substrate is rotated at revolutions enough for improving the shape of an etching boundary.

2. The method of claim 1, wherein supplying the etchant is performed while the substrate is rotated at 300 rpm or more.

3. The method of claim 1, wherein the etchant includes the hydrofluoric acid and the nitric acid at a volume ratio of 1:1 to 1:30.

4. The method of claim 1, wherein a supply amount of the etchant is 3 to 50 cm³/min.

5. The method of claim 1, wherein the hydrophilizing is performed by supplying the nitric acid onto the polysilicon layer formed on the end of the substrate to oxidize the polysilicon layer.

6. The method of claim 5, wherein the hydrophilizing is performed by supplying the nitric acid onto the polysilicon layer formed on the end of the substrate to oxidize the polysilicon layer while the substrate is rotated at 600 rpm or less.

7. The method of claim 1, wherein the hydrophilizing is performed by supplying any one of a hydrogen peroxide solution, an ozonized water and an ozone gas onto the polysilicon layer formed on the end of the substrate to oxidize the polysilicon layer.

8. The method of claim 1, wherein the hydrophilizing is performed by irradiating light onto the polysilicon layer formed on the end of the substrate.

9. The method of claim 8, wherein the light irradiated onto the polysilicon layer is ultraviolet rays.

10. A computer readable storage medium storing a program that controls a processing apparatus, wherein the program controls the processing apparatus to perform the method of claim 1.
